(19) United States
(12) Patent Application Publication
(10) Pub. No.: US 2024/0222311 A1
(43) Pub. Date: Jul. 4, 2024

(54) SEMICONDUCTOR DEVICE HAVING CONNECTION WIRING TO WHICH WIRE IS CONNECTED

(71) Applicant: FUJI ELECTRIC CO., LTD., Kawasaki-shi (JP)

(72) Inventors: Ryoichi KATO, Matsumoto-city (JP); Yuichiro HINATA, Matsumoto-city (JP); Yuma MURATA, Matsumoto-city (JP)

(73) Assignee: FUJI ELECTRIC CO., LTD., Kawasaki-shi (JP)

(21) Appl. No.: 18/605,500

(22) Filed: Mar. 14, 2024

Related U.S. Application Data
(63) Continuation of application No. PCT/JP2023/008664, filed on Mar. 7, 2023.

(30) Foreign Application Priority Data
Apr. 25, 2022 (JP) 2022-071586

(51) Int. Cl. H01L 23/00; H01L 23/538; H01L 25/07

(52) U.S. Cl. CPC H01L 24/40; H01L 23/5386; H01L 24/37; H01L 24/73; H01L 25/072; H01L 24/45; H01L 24/48; H01L 2224/37124; H01L 2224/37147; H01L 2224/37655; H01L 2224/37663; H01L 2224/40091; H01L 2224/40225; H01L 2224/45124; H01L 2224/45144; H01L 2224/45147; H01L 2224/48137; H01L 2224/48227; H01L 2224/73221; H01L 2924/01005; H01L 2924/01015; H01L 2924/0132; H01L 2924/10272; H01L 2924/13055; H01L 2924/13091

(57) ABSTRACT

A semiconductor device including: first and second conductive portions having a gap therebetween; connection wiring including first and second bonding portions respectively bonded to front surfaces of the first and second conductive portions, and a wiring portion straddling the gap and connecting the first and second bonding portions; and a wire bonded to the wiring portion. The wiring portion includes: a vertical portion extending, from a lower end to an upper end thereof, perpendicularly to the first conductive portion, the lower end being connected to the first bonding portion; a parallel portion extending in parallel to the first and second conductive portions from the upper end of the vertical portion, the parallel portion having, on a front surface thereof, a wire bonding portion to which one end of the wire is bonded; and an inclined portion extending inclinedly from the parallel portion toward the second bonding portion.

### CROSS-REFERENCE TO RELATED APPLICATION

This application is a continuation application of International Application filed on Mar. 7, 2023, which PCT/JP2023/008664 designated the U.S., which claims priority to Japanese Patent Application 2022-071586, filed on Apr. 25, 2022, the entire contents of which are incorporated herein by reference.

### BACKGROUND OF THE INVENTION

### 1. Field of the Invention

The embodiment discussed herein relates to a semiconductor device.

### 2. Background of the Related Art

Semiconductor devices include power devices. As one example, semiconductor devices of this type include a power converter function. Power devices are semiconductor chips including insulated gate bipolar transistors (IGBT) and power metal oxide semiconductor field effect transistors (MOSFET).

A semiconductor device further includes a circuit board on which semiconductor chips are mounted and connection wiring (such as a lead frame) that electrically connects the circuit board and the semiconductor chips, and is encapsulated using an encapsulating member. The connection wiring connects main electrodes on the front surfaces of the semiconductor chips and wiring boards provided on the circuit board (see, for example, International Publication Pamphlet No. WO2015/059882, Japanese Laid-open Patent Publication No. 2003-332393, Japanese Laid-open Patent Publication No. 2016-004796, and Japanese Laid-open Patent Publication No. 2019-071399). The semiconductor device may further include a shunt resistor. This shunt resistor may also be directly connected by the connection wiring to a wiring board on the circuit board (see, for example, Japanese Laid-open Patent Publication No. 2019-075521 and Japanese Laid-open Patent Publication No. 2019-075959). In place of a circuit board, the semiconductor device may include a lead frame on which the semiconductor chips are disposed (see International Publication Pamphlet No. WO2015/151273, Japanese Laid-open Patent Publication No. 2013-243394, and Japanese Laid-open Patent Publication No. 61-137352). The semiconductor device may include wires for source sensing. Such wires may also be bonded to the connection wiring (see, for example, Japanese Laid-open Patent Publication No. 2016-004796 and Japanese Laid-open Patent Publication No. 2019-071399).

The encapsulating member of a semiconductor device may suffer from poor adhesion depending on the components to be encapsulated. As one example, the encapsulating member has low adhesion to the solder that bonds the connection wiring to the circuit board. When part of the encapsulating member has low adhesion, peeling may occur at such part and may then spread with this location as the starting point. When the peeling spreads to a wire for source sensing that has been bonded to the connection wiring, there is the risk of the wire breaking due to the peeling.

### SUMMARY OF THE INVENTION

According to an aspect, there is provided a semiconductor device, including: a first conductive portion and a second conductive portion provided with a gap in between; connection wiring, including: a first bonding portion bonded to a front surface of the first conductive portion, a second bonding portion bonded to a front surface of the second conductive portion, and a wiring portion that straddles the gap and connects the first bonding portion and the second bonding portion; and a wire bonded to the wiring portion, wherein the wiring portion includes: a vertical portion that extends, from a lower end thereof to an upper end thereof, perpendicularly to the front surface of the first conductive portion, the lower end thereof being connected to the first bonding portion; a parallel portion that extends in parallel to the first conductive portion and the second conductive portion from the upper end of the vertical portion, the parallel portion having, on a front surface thereof, a wire bonding portion to which one end of the wire is bonded; and an inclined portion that extends inclinedly from the parallel portion toward the second bonding portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a plan view of a housing region in a case included in the semiconductor device according to the present embodiment;

FIG. 3 is a plan view of a semiconductor unit included in the semiconductor device according to the present embodiment;

FIG. 4 is a plan view of an insulated circuit board of a semiconductor unit included in the semiconductor device according to the present embodiment;

FIG. 5 is a cross-sectional view of a semiconductor unit included in the semiconductor device according to the present embodiment;

FIG. 6 is a cross-sectional view of a lead frame included in the semiconductor device according to the present embodiment;

FIG. 7 is a plan view of a lead frame included in the semiconductor device according to the present embodiment;

FIG. 8 is a cross-sectional view (before wire bonding) of a lead frame included in a semiconductor device that is a comparative example;

FIG. 9 is a cross-sectional view (after wire bonding) of the lead frame included in the semiconductor device that is the comparative example;

FIG. 10 is a cross-sectional view of a lead frame included in a semiconductor device according to the present embodiment (Modification 1);

FIG. 11 is a plan view of the lead frame included in the semiconductor device according to the present embodiment (Modification 1);

FIG. 12 is a cross-sectional view of a lead frame included in a semiconductor device according to the present embodiment (Modification 2); and

FIG. 13 is a plan view of the lead frame included in the semiconductor device according to the present embodiment (Modification 2).

### DETAILED DESCRIPTION OF THE INVENTION

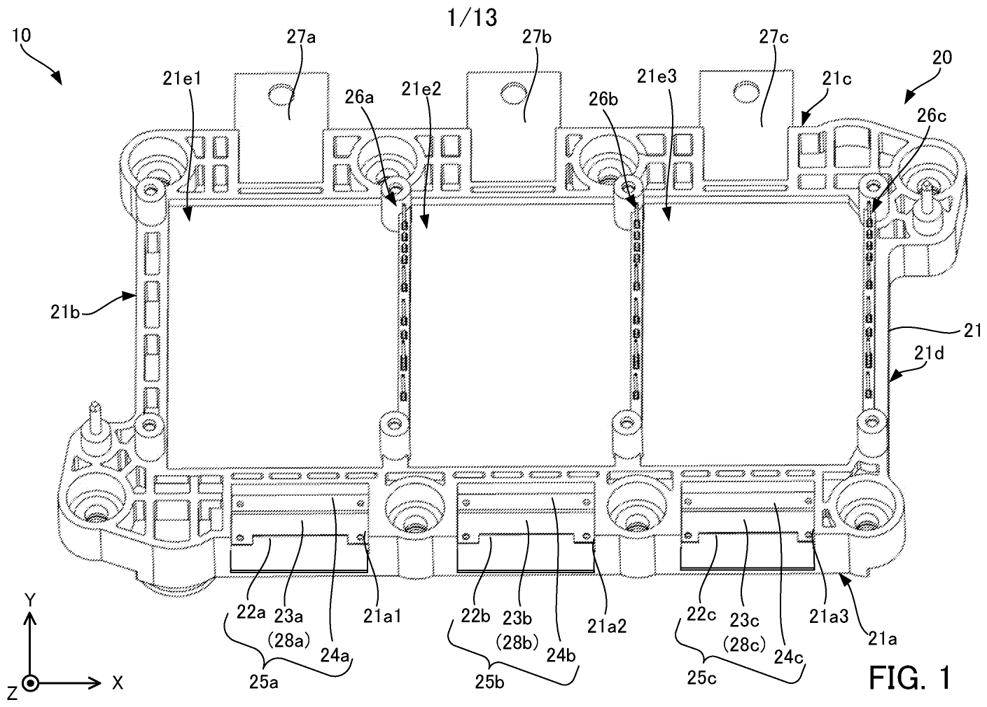

An embodiment will be described below with reference to the accompanying drawings. Note that in the following description, the expressions “front surface” and “upper surface” refer to an X-Y plane that faces upward (in the “+Z direction”) for a semiconductor device 10 in the drawings. In the same way, the expression “up” refers to the upward direction (or “+Z direction”) for the semiconductor device 10 depicted in FIG. 1. The expressions “rear surface” and “lower surface” refer to an X-Y plane that faces downward (that is, in the “−Z direction”) for the semiconductor device 10 depicted in the drawings. In the same way, the expression “down” refers to the downward direction (or “−Z direction”) for the semiconductor device 10 depicted in FIG. 1. These expressions are used as needed to refer to the same directions in the other drawings. The expression “high” refers to an upper (that is, “+Z side”) position on the semiconductor device 10 in the drawings. In the same way, the expression “low” refers to a lower (that is, “−Z side”) position on the semiconductor device 10 in the drawings. The expressions “front surface”, “upper surface”, “up”, “rear surface”, “lower surface”, “down”, and “side surface” are merely convenient expressions used to specify relative positional relationships, and are not intended to limit the technical scope of the present embodiment. As one example, “up” and “down” do not necessarily mean directions that are perpendicular to the ground. That is, the “up” and “down” directions are not limited to the direction of gravity. Additionally, in the following description, the expression “main component” refers to a component that composes 80% or higher by volume.

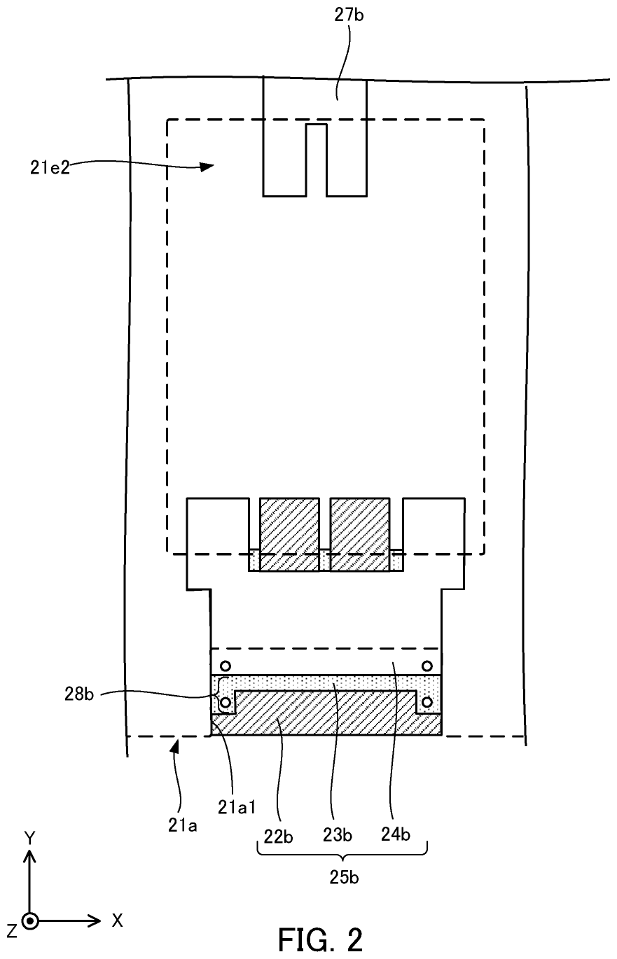

A semiconductor device according to the present embodiment will be described with reference to FIGS. 1 and 2. FIG. 1 is a plan view of a semiconductor device according to an embodiment, and FIG. 2 is a plan view of a housing region in a case included in the semiconductor device according to the present embodiment. Note that FIG. 2 is a plan view of a terminal stack 25b (a first power terminal 22b, an insulating sheet 23b, and a second power terminal 24b) of the semiconductor device 10. A housing region 21e2 in a main body 21 is indicated by a broken line. Although FIG. 2 depicts only the housing region 21e2 and the terminal stack 25b, housing regions 21el and 21e3 and terminal stacks 25a and 25c may also be depicted in the same manner.

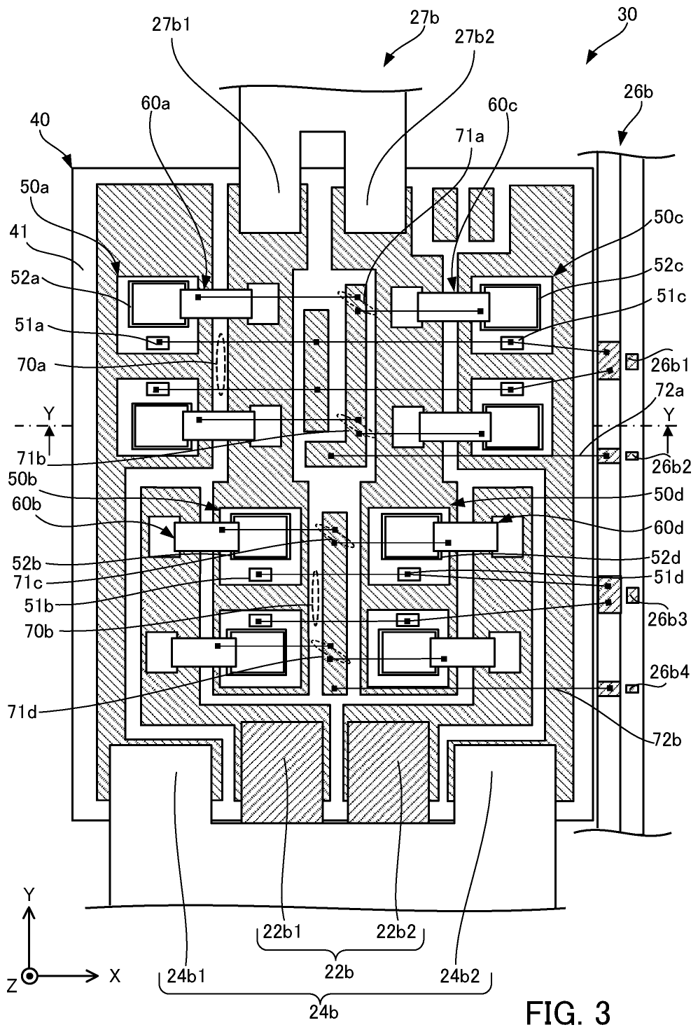

The semiconductor device 10 includes semiconductor units (not illustrated), a heat-dissipating base plate (not illustrated) on which the semiconductor units are disposed, and a case 20 that is disposed on the heat-dissipating base plate and houses the semiconductor units. Note that the semiconductor units and the heat-dissipating base plate will be described in detail later. The case 20 includes the main body 21, the terminal stacks 25a to 25c, a U terminal 27a, a V terminal 27b, a W terminal 27c, and control terminals (not illustrated here, see FIG. 3).

The main body 21 is substantially rectangular when viewed from above, and is surrounded on all four sides by first to fourth side portions 21a to 21d in that order. The first side portion 21a and the third side portion 21c correspond to long sides, and the second side portion 21b and the fourth side portion 21d correspond to short sides. Note that the main body 21 depicted in FIG. 1 has a configuration where fastening holes are provided at a corner portion formed by the first side portion 21a and the second side portion 21b and a corner portion formed by the third side portion 21c and the fourth side portion 21d.

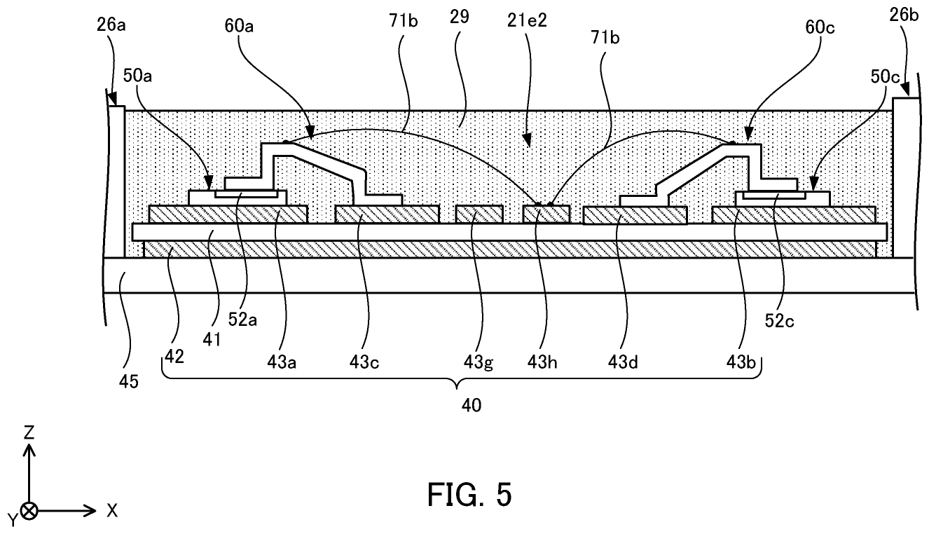

The main body 21 includes housing regions 21e1 to 21e3 and control frame portions 26a to 26c. The housing regions 21el to 21e3 are partitioned by the control frame portions 26a and 26b. The housing regions 21el to 21e3 are partitioned by the control frame portions 26a and 26b in an intermediate part of the main body 21 when looking from above, and are spaces that are provided along the length direction (that is, along the first and third side portions 21a and 21c) of the main body 21. Note that the fourth side portion 21d of the housing region 21e3 may include the control frame portion 26c. A semiconductor unit is housed in each of the housing regions 21el to 21e3. When looking from above, the housing regions 21el to 21e3 may each be shaped and sized so as to be capable of housing a semiconductor unit. As one example, this shape may be rectangular. When semiconductor units have been housed in the housing regions 21e1 to 21e3, as depicted in FIG. 1, the inside of the housing regions 21el to 21e3 is encapsulated with encapsulating resin (see the encapsulating member 29 in FIG. 5). The encapsulating member includes a thermosetting resin and a filler included in the thermosetting resin. As examples, the thermosetting resin is epoxy resin, phenol resin, or maleimide resin. The filler is silicon oxide, aluminum oxide, boron nitride, or aluminum nitride.

The main body 21 includes the terminal stacks 25a to 25c along the first side portion 21a. The terminal stacks 25a to 25c are exposed from the first side portion 21a. The main body 21 includes the U terminal 27a, the V terminal 27b, and the W terminal 27c along the third side portion 21c. The U terminal 27a, the V terminal 27b, and the W terminal 27c are exposed from a front surface of the third side portion 21c. Control terminals are provided on each of the control frame portions 26a to 26c.

The main body 21 and the control frame portions 26a to 26c are molded using thermoplastic resin. As examples, the thermoplastic resin is polyphenylene sulfide (PPS) resin, polybutylene terephthalate (PBT) resin, polybutylene succinate (PBS) resin, polyamide (PA) resin, or acrylonitrile butadiene styrene (ABS) resin. The main body 21 is molded by insert molding from such materials so as to include the terminal stacks 25a to 25c, the U terminal 27a, the V terminal 27b, and the W terminal 27c. The control frame portions 26a to 26c are formed by insert molding so as to include the control terminals. The control frame portions 26a to 26c may be separately attached to the main body 21.

The terminal stacks 25a to 25c are produced by stacking first power terminals 22a to 22c, insulating sheets 23a to 23c, and second power terminals 24a to 24c, respectively.

One end of the front surface of each first power terminals 22a to 22c is exposed along the length direction (that is, along the first side portion 21a) to terminal regions 21a1 to 21a3 on the first side portion 21a of the main body 21. Here, one end of each of the first power terminals 22a to 22c protrudes outward (in the −Y direction) from the first side portion 21a. The other ends of the first power terminals 22a to 22c are electrically connected on the inside of the main body 21 (that is, inside the housing regions 21el to 21e3) to locations that correspond to the N terminals of the semiconductor chips included in the semiconductor units. The first power terminals 22a to 22c are shaped as flat plates. The first power terminals 22a to 22c are made of metal with superior conductivity. Examples of such metals are copper, copper alloy, aluminum, and aluminum alloy.

One end of the front surface of each second power terminal 24a to 24c protrudes outward (in the −Y direction) from the first side portion 21a. The second power terminals 24a to 24c are exposed along the length direction (that is, along the first side portion 21a) on the first side portion 21a of the main body 21. The one end of each of the second power terminals 24a to 24c is disposed so as to be exposed. Note that front end portions (or “terrace portions” 28a, 28b, 28c) of the insulating sheets 23a to 23c are positioned between the front end portions of the first power terminals 22a to 22c and the front end portions of the second power terminals 24a to 24c when looking from above. By doing so, electrical insulation is maintained between the first power terminals 22a to 22c and the second power terminals 24a to 24c. The other ends of the second power terminals 24a to 24c are electrically connected inside the main body 21 (that is, inside the housing regions 21el to 21e3) to locations corresponding to P terminals of the semiconductor chips included in the semiconductor units. The second power terminals 24a to 24c are shaped as flat plates. The second power terminals 24a to 24c are made of metal with superior conductivity. Examples of such metals are copper, copper alloy, aluminum, and aluminum alloy.

The insulating sheets 23a to 23c are made of an insulating material that is electrically insulating. Examples of such insulating material include insulating paper made of a wholly aromatic polyamide polymer, or a sheet-like material formed of a fluorine-based or polyimide-based resin material.

The control terminals included in the control frame portions 26a to 26c are included by insert molding along the control frame portions 26a to 26c. As one example, as depicted in FIG. 3, described later, control terminals 26b1 to 26b4 included in the control frame portion 26b are J-shaped when viewed from the side (that is, when looking from the arrow in the Y direction). One end of each of the control terminals 26b1 to 26b4 extends vertically upward (in the +Z direction) from the front surface of the control frame portion 26b. The other ends of the control terminals 26b1 to 26b4 are exposed to the housing region 21e2 side of the control frame portion 26b. The control terminals 26b1 and 26b3 are directly connected inside the housing region 21e2 by wiring members to the control electrodes of the semiconductor chips included in the semiconductor units. The control terminals 26b2 and 26b4 are electrically connected inside the housing region 21e2 to the output electrodes of the semiconductor chips included in the semiconductor units. In the same way as the control frame portion 26b, the control terminals included in the control frame portions 26a and 26c (not illustrated) are connected inside the housing regions 21e1 and 21e3 by wiring members to the control electrodes of the semiconductor chips included in the semiconductor units. Note that as examples, the wiring members are wires 70a, 70b, 71a, 71b, 71c, 71d, 72a, and 72b. Alternatively, the wiring members may be lead frames. The wiring members are made of a material with superior conductivity. Examples of such materials include metals (such as aluminum and copper) or alloys containing at least one of these metals. The control terminals are also made of metal with superior conductivity. Examples of such metal include copper, copper alloy, aluminum, and aluminum alloy.

The other ends of the U terminal 27a, the V terminal 27b, and the W terminal 27c are electrically connected inside the housing regions 21el to 21e3 to the source electrodes (or emitter electrodes) of the semiconductor chips of the semiconductor units. Note that FIG. 2 depicts the V terminal 27b. The other ends of the U terminal 27a and the W terminal 27c are provided in the same manner with respect to the housing regions 21e1 and 21e3. On the third side portion 21c of the main body 21, one end of each of the U terminal 27a, the V terminal 27b, and the W terminal 27c are exposed along the length direction (of the third side portion 21c) of the main body 21. The other ends of the second power terminals 24a to 24c are electrically connected inside the main body 21 (that is, inside the housing regions 21el to 21e3) to locations corresponding to P terminals of the semiconductor chips included in the semiconductor units. The U terminal 27a, the V terminal 27b, and the W terminal 27c with superior are made of metal conductivity. Examples of such metals include copper, copper alloy, aluminum, and aluminum alloy.

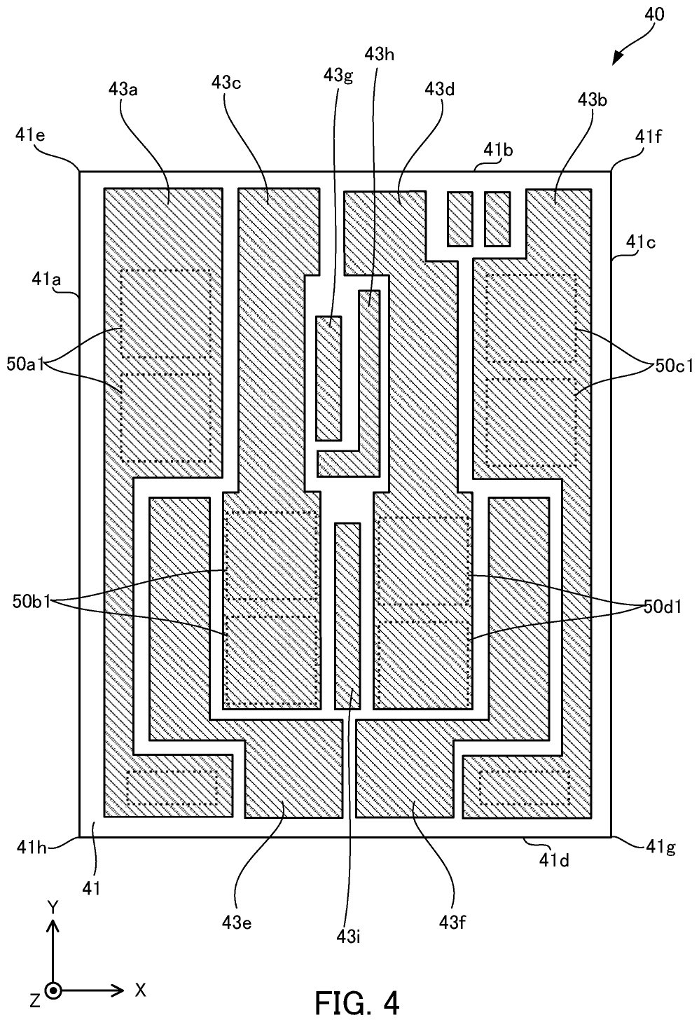

Next, the semiconductor unit disposed on the heat-dissipating base plate will be described with reference to FIG. 3 to FIG. 5. FIG. 3 is a plan view of a semiconductor unit included in the semiconductor device according to the present embodiment. FIG. 4 is a plan view of an insulated circuit board of a semiconductor unit included in the semiconductor device according to the present embodiment. FIG. 5 is a cross-sectional view of a semiconductor unit included in the semiconductor device according to the present embodiment. Note that FIG. 4 depicts only the insulated circuit board appearing in FIG. 3. FIG. 5 is a cross-sectional view taken along the chain line Y-Y in FIG. 3. As depicted in FIG. 5, a semiconductor unit 30 is disposed on the heat-dissipating base plate 45 via a bonding member (not illustrated). Note that the case 20 is disposed on the heat-dissipating base plate 45 via an adhesive. When doing so, a semiconductor unit 30 is housed in each of the housing regions 21el to 21e3 of the case 20. Each semiconductor unit 30 includes an insulated circuit board 40, semiconductor chips 50a to 50d, and lead frames 60a to 60d.

Note that solder or sintered material is used as a bonding member that bonds the heat-dissipating base plate 45 to the semiconductor units 30 (the insulated circuit boards 40). Lead-free solder or leaded solder is used as the solder. Lead-free solder has an alloy containing at least two of tin, silver, copper, zinc, antimony, indium, and bismuth, for example, as a main component. The solder may additionally contain additives. Example additives are nickel, germanium, cobalt, and silicon. Including additives in the solder improves wettability, gloss, and bonding strength, which improves reliability. Leaded solder additionally contains lead. As one example, a metal material containing at least one of copper, copper alloy, nickel, nickel alloy, silver, and silver alloy is used as the sintered material.

The insulated circuit board 40 is rectangular when viewed from above. The insulated circuit board 40 includes an insulating board 41, a metal plate 42 formed on a rear surface of the insulating board 41, and a plurality of wiring boards 43a to 43g formed on the front surface of the insulating board 41. When looking from above, the outer shapes of the plurality of wiring boards 43a to 43g and the metal plate 42 are smaller than the outer shape of the insulating plate 41, and are formed inside the outline of the insulating plate 41. Note that the shapes, number, and sizes of the plurality of wiring boards 43a to 43g in the present embodiment are mere examples. The plurality of wiring boards 43a to 43g are a specific example of “conductive portions” (“second conductive portions”).

The insulating board 41 is rectangular when viewed from above. The corner portions of the insulating board 41 may be chamfered. As examples, the corner portions may be chamfered into rounded or beveled shapes. The insulating board 41 is surrounded on all four sides by a long side 41a, a short side 41b, a long side 41c, and a short side 41d in that order as outer circumferential sides. The insulating board 41 also includes corner portions 41e to 41h. The corner portion 41e is formed by the long side 41a and the short side 41b. The corner portion 41f is formed by the short side 41b and the long side 41c. The corner portion 41g is formed by the long side 41c and the short side 41d. The corner portion 41h is formed by the short side 41d and the long side 41a. This insulating board 41 is made of ceramics with favorable thermal conductivity. Example ceramics are made of a material with aluminum oxide, aluminum nitride, or silicon nitride as a main component. The thickness of the insulating board 41 is 0.2 mm or more and 2.0 mm or less, for example.

The metal plate 42 is rectangular when viewed from above. Corner portions of the metal plate 42 may be chamfered into rounded or beveled shapes, for example. The metal plate 42 is smaller in size than the insulating board 41 and is formed on the entire rear surface of the insulating board 41 except for edge portions. The metal plate 42 is made of a metal with superior thermal conductivity as a main component. Example metals include copper, aluminum, and an alloy including at least one of these metals. The thickness of the metal plate 42 is 0.1 mm or more and 2.0 mm or less, for example. A plating treatment may be performed to improve the corrosion resistance of the metal plate 42. When doing so, examples of the plating material used are nickel, nickel-phosphorus alloy, and nickel-boron alloy.

The wiring boards 43a to 43h are formed across the entire surface of the insulating board 41 except for edge portions. When looking from above, it is preferable for edges of the wiring boards 43a to 43g that face the outer circumference of the insulating board 41 to coincide with edges of the metal plate 42 on the outer circumference sides of the insulating board 41. This results in a favorable balance in stress being maintained in the insulated circuit board 40 with the metal plate 42 on the rear surface of the insulating board 41. By doing so, damage, such as excessive warping and cracking of the insulating board 41, is suppressed. Note that the two regions indicated with broken lines at the top (in the +Y direction) of each of the wiring boards 43a and 43b respectively indicate chip regions 50al and 50cl of the two semiconductor chips 50a and 50c. The two regions indicated with broken lines at the bottom (in the −Y direction) of each of the wiring boards 43c and 43d respectively indicate chip regions 50b1 and 50dl of the two semiconductor chips 50b and 50d. The thickness of the wiring boards 43a to 43h is 0.1 mm or more and 2.0 mm or less, for example. The wiring boards 43a to 43h are made of a metal with superior electrical conductivity. Example metals are copper, aluminum, or an alloy containing at least one of these metals. A plating treatment may also be performed on the surfaces of the wiring boards 43a to 43h to improve corrosion resistance. When doing so, the plating material used is nickel, nickel-phosphorus alloy, or nickel-boron alloy, for example.

The wiring board 43a is formed on the long side 41a of the insulating board 41, from the short side 41b to the short side 41d along the long side 41a. A recess is formed in the long side 41c side of a lower (−Y direction) part of the wiring board 43a. The wiring board 43b is formed so as to substantially have line symmetry with the wiring board 43a about a center line in the +Y direction. The wiring board 43b is formed on the long side 41c of the insulating board 41, from the short side 41b to the short side 41d along the long side 41c. A recess is formed in the long side 41a side of a lower (−Y direction) part of the wiring board 43b.

The wiring board 43c is formed adjacent to the wiring board 43a and in parallel with the long side 41a, and extends in the −Y direction from the short side 41b. A −Y direction end of the wiring board 43c is located away from the short side 41d. A recess is formed midway in a long side 41c side-side portion of an upper (a +Y direction) part of the wiring board 43c. The wiring board 43d is formed so as to substantially have line symmetry with the wiring board 43c about a center line in the ±Y direction. The wiring board 43d is formed adjacent to an upper part (in the +Y direction) of the wiring board 43b, in parallel with the long side 41c, and extends from the short side 41b in the −Y direction. A −Y direction end of the wiring board 43d is located away from the short side 41d. A recess is formed midway in a long side 41a side-side portion of an upper (a +Y direction) part of the wiring board 43d.

The wiring board 43e is disposed in a region surrounded by the lower portion (−Y direction) of the wiring board 43a, the lower portion (−Y direction) of the wiring board 43c, and the short side 41d. That is, the wiring board 43e is substantially L-shaped. The wiring board 43f is formed so as to substantially have line symmetry with respect to the wiring board 43e about the center line in the +Y direction. The wiring board 43f is disposed in a region surrounded by a lower portion (−Y direction) of the wiring board 43b, the wiring board 43d, and the short side 41d. That is, the wiring board 43e is substantially L-shaped.

The wiring board 43g is I-shaped when viewed from above and is disposed in parallel with the long side 41a on a wiring board 43c-side of a region surrounded by the recesses in the wiring boards 43c and 43d. The wiring board 43h is L-shaped when viewed from above and is disposed in parallel with the long side 41c on the wiring board 43d-side of the region surrounded by the recesses in the wiring boards 43c and 43d. The wiring board 43h is disposed so as to surround the long side 41c-side and the short side 41d-side of the wiring board 43g. The wiring board 431 is I-shaped when viewed from above and is disposed in parallel with the long sides 41a and 41c between the wiring boards 43c and 43d.

Bonding portions of one of the second power terminals 24a to 24c are bonded to lower portions (in the −Y direction) of the wiring boards 43a and 43b of each insulated circuit board 40. Note that FIG. 3 illustrates a case where internal bonding portions 24b1 and 24b2 of the second power terminal 24b are bonded to the wiring boards 43a and 43b, respectively. Bonding portions of one of the first power terminals 22a to 22c are bonded to lower portions (in the −Y direction) of the wiring boards 43c and 43d of each insulated circuit board 40. Note that FIG. 3 illustrates a case where internal bonding portions 22b1 and 22b2 of the first power terminal 22b are bonded to the wiring boards 43c and 43d, respectively. Bonding portions of one of the U terminal 27a, the V terminal 27b, and the W terminal 27c are respectively bonded to upper portions (in the +Y direction) of the wiring boards 43c and 43d of each insulated circuit board 40. Note that FIG. 3 illustrates a case where internal connecting portions 27b1 and 27b2 of the V terminal 27b are bonded to the wiring boards 43c and 43d, respectively.

As examples, a direct copper bonding (DCB) board or an active metal brazed (AMB) board may be used as the insulated circuit board 40 with the configuration described above. The insulated circuit board 40 radiates heat generated by the semiconductor chips 50a to 50d, which will be described later, by conducting the heat to the rear surface side of the insulated circuit board 40 via the wiring boards 43a to 43d, the insulating board 41, and the metal plate 42.

The semiconductor chips 50a to 50d are power devices made of silicon carbide. One example of this type of power device is a power MOSFET. These semiconductor chips 50a to 50d are equipped with drain electrodes as input electrodes (main electrodes) on their respective rear surfaces, and gate electrodes as control electrodes 51a to 51d and source electrodes as output electrodes 52a to 52d (main electrodes) on their respective front surfaces (“first front surfaces”). Note that the output electrodes 52a to 52d are a specific example of “conductive portions” (“first conductive portions”). FIG. 5 merely illustrates the output electrodes 52a and 52c of the semiconductor chips 50a and 50c. Likewise, the semiconductor chips 50b and 50d are equipped with the output electrodes 52b and 52d on their respective front surfaces.

The semiconductor chips 50a to 50d may be power devices made of silicon. One example of this type of power device is a reverse conducting (RC)-IGBT. An RC-IGBT is a combination of an IGBT as a switching element and a freewheeling diode (FWD) as a diode element that are implemented in a single chip. As one example, such semiconductor chips 50a to 50d each have a collector electrode as an input electrode (main electrode) on their respective rear surfaces, and a gate electrode as a control electrode and an emitter electrode as an output electrode (main electrode) on their respective front surfaces.

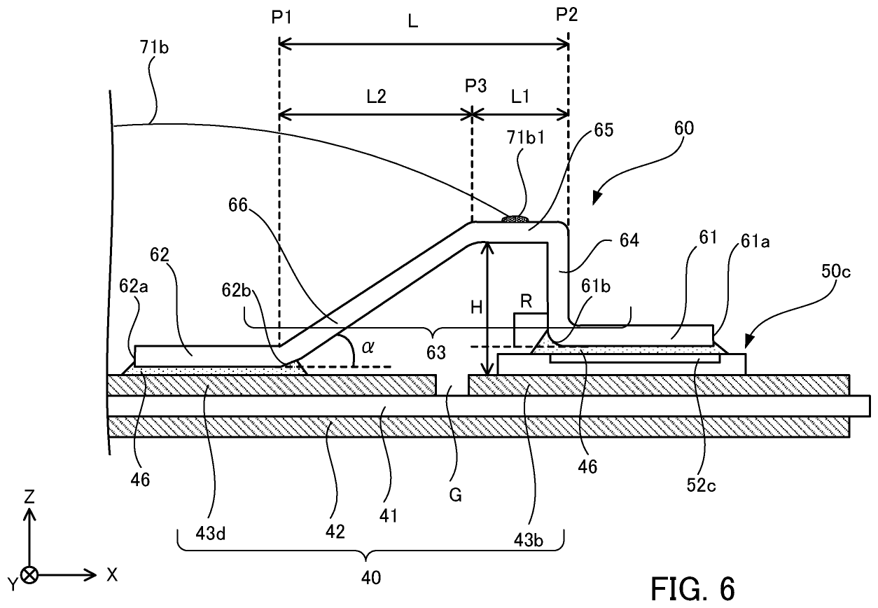

Note that in the present embodiment, a plurality of semiconductor chips 50a to 50d are disposed on the wiring boards 43a to 43d via the bonding members (see the bonding member 46 in FIG. 6) described above. FIG. 3 depicts a configuration where chips are disposed in pairs. In this case, the semiconductor chips 50a to 50d are disposed so that the control electrodes 51a to 51d of the chips in a pair face each other.

The lead frames 60a to 60d electrically connect the output electrodes on the front surfaces of the semiconductor chips 50a to 50d and the wiring boards 43a to 43f. Each lead frame 60a electrically and mechanically connects a semiconductor chip 50a and the wiring board 43c. Each lead frame 60b electrically and mechanically connects a semiconductor chip 50b and the wiring board 43e. Each lead frame 60c electrically and mechanically connects a semiconductor chip 50c and the wiring board 43d. Each lead frame 60d electrically and mechanically connects a semiconductor chip 50d and the wiring board 43f.

One end of each lead frame 60a to 60d is bonded to the output electrode of one of the semiconductor chips 50a to 50d using the solder described above as a bonding member 46. The other end of each lead frame 60a to 60d is bonded to one of the wiring boards 43c, 43e, 43d, and 43f using the bonding member 46 described above. The lead frames 60a to 60d are made of a material with superior electrical conductivity. As examples, such material may be copper, aluminum, or an alloy containing at least one of these metals. The surfaces of the lead frames 60a to 60d may also be subjected to a plating treatment to improve corrosion resistance. As examples, the plating material in this case may be nickel, nickel-phosphorus alloy, or nickel-boron alloy. When not distinguishing between them, the lead frames 60a to 60d are described below as the “lead frames 60”. The lead frames 60 will be described in detail later.

The control electrodes 51a to 51d of the semiconductor chips 50a to 50d are electrically connected by wires to control terminals included on the control frame portions 26a to 26c. As one example, as depicted in FIG. 3, the control electrodes 51a of the semiconductor chips 50a are electrically connected to the control terminal 26b1 via wires 70a that are linked via the wiring board 43g. The control electrodes 51b and 51d of the semiconductor chips 50b and are electrically connected via the wires 70b to the control terminal 26b3. The control electrodes 51c of the semiconductor chips 50c are electrically connected via the wires 70a to the control terminal 26b1.

The lead frames 60a and 60c are electrically and mechanically connected via wires 71a and 71b to the wiring board 43h. Additionally, the wiring board 43h is electrically and mechanically connected via a wire 72a to the control terminal 26b2. That is, the lead frames 60a and 60c are electrically connected to the control terminal 26b2. The lead frames 60b and 60d are electrically and mechanically connected via wires 71c and 71d to the wiring board 431. Additionally, the wiring board 43i is electrically and mechanically connected via a wire 72b to the control terminal 26b4. That is, the lead frames 60b and 60d are electrically connected to the control terminal 26b4. The control terminals 26b2 and 26b4 are used for source sensing.

The wires 70a, 70b, 71a, 71b, 71c, 71d, 72a, and 72b described above have a material with superior electrical conductivity as a main component. Examples of such a material include gold, copper, aluminum, or an alloy containing at least one of these metals. The wires 70a, 70b, 71a, 71b, 71c, 71d, 72a, and 72b may preferably be made of aluminum alloy containing a trace amount of silicon. As examples, the diameter of the wires 70a, 70b, 71a, 71b, 71c, 71d, 72a, and 72b is 100 μm or more and 400 μm or less.

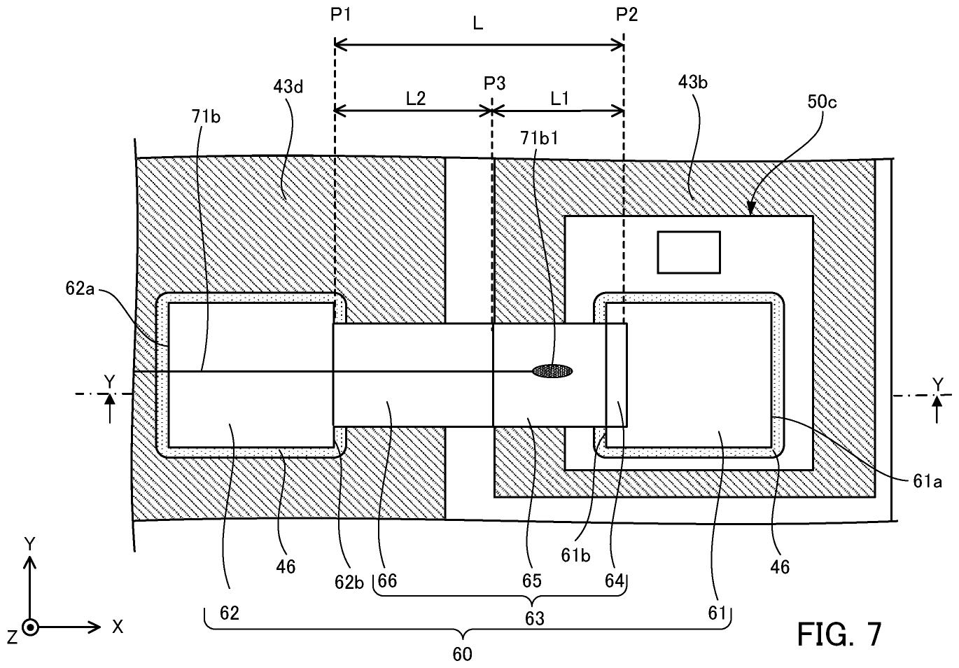

Next, the lead frames 60a to 60d will be described in detail with reference to FIGS. 6 and 7. FIG. 6 is a cross-sectional view of a lead frame included in the semiconductor device according to the present embodiment, and FIG. 7 is a plan view of a lead frame included in the semiconductor device according to the present embodiment. Note that FIGS. 6 and 7 correspond to the lead frame 60c in FIG. 3. Since the other lead frames have similar configurations, the expression “the lead frames 60” is used here.

The lead frames 60 are a specific example of connection wiring. Each lead frame 60 includes a chip bonding portion 61 (“first bonding portion”), a wiring bonding portion 62 (“second bonding portion”), and a wiring portion 63. The chip bonding portion 61 is bonded to the output electrode 52c on the front surface of the semiconductor chip 50c via the bonding member 46. In this case, as described earlier, the bonding member 46 may be solder. The wiring bonding portion 62 is bonded to the front surface of the wiring board 43d (“second front surface”). The wiring bonding portion 62 is bonded by the bonding member 46 described earlier to the wiring board 43d. Alternatively, such bonding is achieved by ultrasonic bonding. The wiring portion 63 spans a gap G between the wiring boards 43d and 43b and connects the chip bonding portion 61 and the wiring bonding portion 62. This lead frame 60 is in the overall shape of a flat plate in which the chip bonding portion 61, the wiring bonding portion 62, and the wiring portion 63 are integrally connected. The thickness of the lead frame 60 is substantially uniform across the entire lead frame 60, and as example may be 0.2 mm or more and 0.6 mm or less, and more preferably 0.3 mm or more and 0.5 mm or less. The chip bonding portion 61 is rectangular in shape when viewed from above in the same way as the shape of the output electrode 52c of the semiconductor chip 50c when viewed from above. The area of the chip bonding portion 61 when looking from above may be 60% or more and 95% or less of the area of the output electrode 52c of the semiconductor chip 50c when looking from above.

The wiring portion 63 includes a vertical portion 64, a parallel portion 65, and an inclined portion 66. A lower end of the vertical portion 64 is connected to the chip bonding portion 61, and an upper end of the vertical portion 64 rises vertically from the chip bonding portion 61. Accordingly, an angle R between the vertical portion 64 and the chip bonding portion 61 is approximately 90 degrees. The angle R may effectively be 90 degrees. Although the angle R is preferably 90 degrees, the angle R may be greater than or equal to 80 degrees and less than 90 degrees. In the present embodiment, unless otherwise specified, the description will assume that the angle R is 90 degrees. An outer side (that is, the wiring board 43b side) of a connection (or “heel portion 61b”) between the lower end of the vertical portion 64 and the chip bonding portion 61 may be rounded. Alternatively, the connection may be chamfered (beveled). For this reason, at a toe portion 61a (in the +X direction) of the chip bonding portion 61, the bonding member 46 that bonds the chip bonding portion 61 to the semiconductor chip 50c is shaped as a fillet. At a heel portion 61b (in the −X direction) of the chip bonding portion 61 also, the bonding member 46 is shaped as a fillet that covers an outside of the connection with the vertical portion 64. Note that side portions of the chip bonding portion 61 that are perpendicular to the toe portion 61a and the heel portion 61b are also shaped as fillets.

The parallel portion 65 is connected to the upper end of the vertical portion 64 and extends from this upper end in parallel with the wiring boards 43b and 43d and the semiconductor chip 50c. Since the wiring portion 63 straddles the gap G, the parallel portion 65 extends from the upper end of the vertical portion 64 bonding toward the wiring portion 62. In this configuration also, the outside of the connection P2 between the parallel portion 65 and the vertical portion 64 may be rounded. Alternatively, the outside may be chamfered (beveled). The angle formed by the parallel portion 65 and the vertical portion 64 is approximately 90 degrees. This angle may also effectively be 90 degrees.

One end (or “wire bonding portion 71b1”) of the wire 71b is bonded to a front surface of the parallel portion 65. The other end of the wire 71b is bonded to the wiring board 43h (which is adjacent to the wiring board 43d in the −X direction). As described earlier, the wire 71b is bonded to the parallel portion 65 by a bonding device. In the bonding device, ultrasonic waves are applied while pressing the one end of the wire 71b against the parallel portion 65. When doing so, the wire bonding portion 71b1, which results from plastic deformation of the one end of the wire 71b, is bonded to the parallel portion 65. The wire bonding portion 71b1 may extend in any direction in keeping with the direction of vibration of the ultrasonic waves. In the present embodiment, the wire bonding portion 71b1 extends in the wiring direction (±X direction) of the wiring portion 63, and is elliptical in shape when viewed from above. Also, in the present embodiment, the wire 71b is laid out in a straight line with respect to the long axis of the wire bonding portion 71b1.

The inclined portion 66 is inclined from the parallel portion 65 toward the wiring bonding portion 62. The angle of inclination of the inclined portion 66 with respect to the wiring bonding portion 62 is assumed to be an angle α. An outside (or upper side) of a connection P3 between the inclined portion 66 and the parallel portion 65 may be rounded. Alternatively, the outside may be chamfered (beveled). The outside (or wiring board 43d side) of a connection P1 (or “heel portion 62b”) between the inclined portion 66 and the wiring bonding portion 62 may be rounded. Alternatively, the outside may be chamfered (beveled). For this reason, at a toe portion 62a (in the −X direction) of the wiring bonding portion 62, the bonding member 46 that bonds the wiring bonding portion 62 to the wiring board 43d is shaped as a fillet. At a heel portion 62b (in the ±X direction) of the wiring bonding portion 62 also, the bonding member 46 is shaped as a fillet that covers an outside (or wiring board 43d side) of the connection P1 with the inclined portion 66.

For the wiring portion 63 of the lead frame 60, the length between the connections P1 and P2 is defined as “length L”. That is, the length L is the distance in the ±X direction between the heel portion 61b of the chip bonding portion 61 and the heel portion 62b of the wiring bonding portion 62. Out of the length L, the length between the connections P2 and P3 is defined as “length L1”. That is, the length L1 is the length of the parallel portion 65 in the ±X direction along the wiring direction of the lead frame 60. Out of the length L, the length between the connections P3 and

P1 when looking from above is defined as “length L2”. That is, the length L2 is the length, when looking from above, in the ±X direction of the inclined portion 66 along the wiring direction of the lead frame 60. The actual length of the inclined portion 66 along the wiring direction of the lead frame 60 is expressed as length “L2/COS α”.

The width of the wiring portion 63 when looking from above (that is, the width in a direction (or “+Y direction”) that is perpendicular to the wiring direction (or “±X direction”) of the lead frame 60) may be substantially uniform across the wiring portion 63. The width of the wiring portion 63 may be smaller than the widths of the chip bonding portion 61 and the wiring bonding portion 62. Part of the wiring portion 63 may have a narrower width. To stabilize the wiring portion 63, it is preferable for the width of the wiring portion 63 to be substantially uniform across the entire wiring portion 63. For further stability, it is more preferable for the width of the lead frame 60 to be substantially uniform across the entire lead frame 60.

The angle α for the wiring portion 63 may be changed. When the angle α is increased, the length L2 becomes shorter and the length L1 becomes longer. On the other hand, when the angle α is made smaller, the length L2 becomes longer and the length L1 becomes shorter. The wire 71b is bonded to the front surface of the parallel portion 65. For this reason, it is preferable for the angle α so that the parallel portion 65 has a sufficient area (the length L1) for bonding purposes.

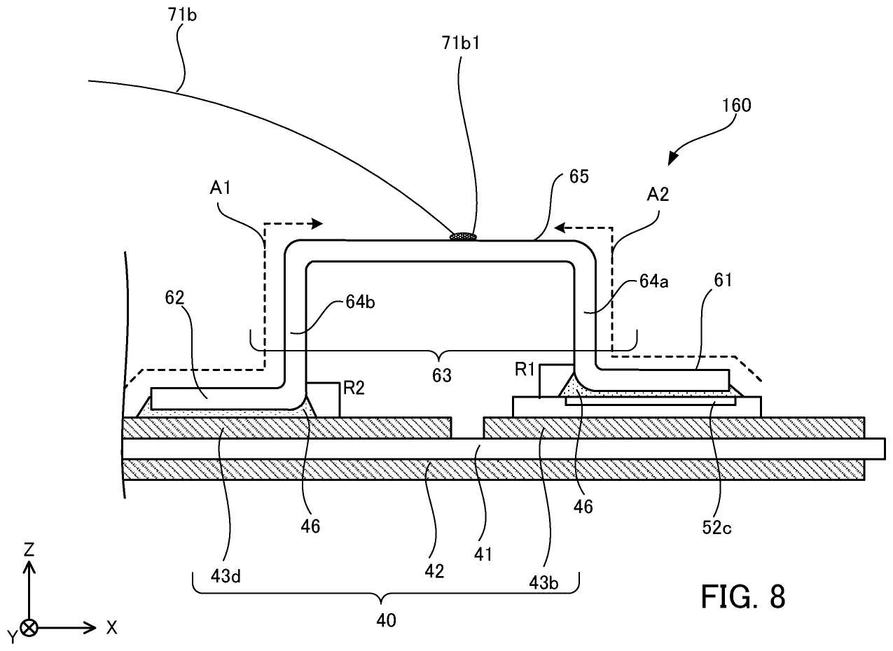

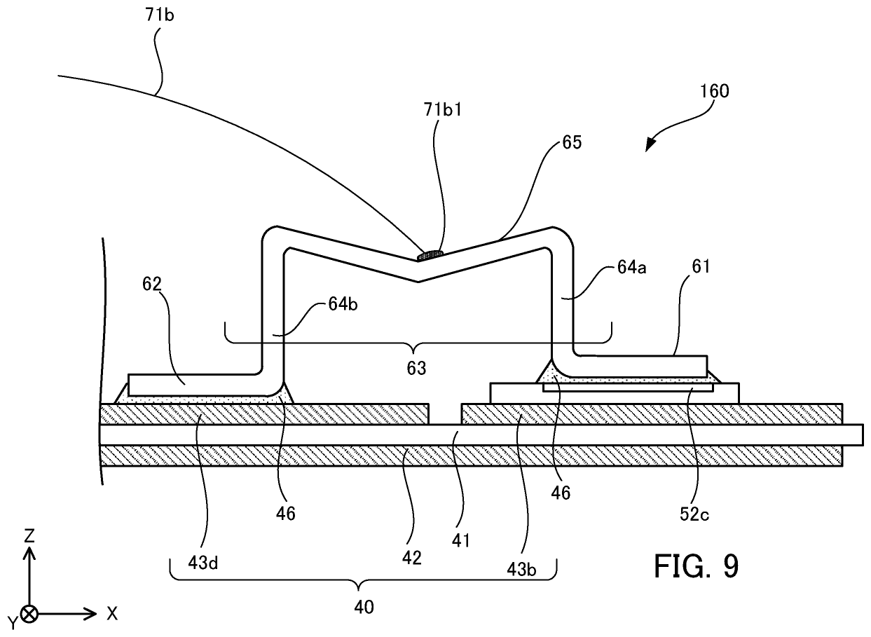

Next, an example configuration to be compared with the lead frames 60 will be described with reference to FIGS. 8 and 9. FIG. 8 is a cross-sectional view (before wire bonding) of a lead frame included in a semiconductor device that is a comparative example, and FIG. 9 is a cross-sectional view (after wire bonding) of the lead frame included in the semiconductor device that is the comparative example. In this comparative example, a lead frame 160 is provided in place of the lead frame 60 in FIGS. 6 and 7. The other configurations are the same as those in FIGS. 6 and 7.

The lead frame 160 includes the chip bonding portion 61, the wiring bonding portion 62, and the wiring portion 63. The wiring portion 63 of the comparative example further includes a vertical portion 64a, a parallel portion 65, and a vertical portion 64b. In the same way as the vertical portion 64, the lower end of the vertical portion 64a is connected to the chip bonding portion 61 and the upper end of the vertical portion 64a rises vertically from the chip bonding portion 61. An angle R1 formed by the vertical portion 64a and the chip bonding portion 61 is approximately 90 degrees. The angle R1 may effectively be 90 degrees.

In the same way as the parallel portion 65 included in the lead frame 60, the parallel portion 65 is connected to the upper end of the vertical portion 64a, and extends from the upper end in parallel with the wiring boards 43b, 43d and the semiconductor chip 50c. The vertical portion 64b extends vertically

from the parallel portion 65 toward the wiring bonding portion 62. The vertical portion 64b is at an angle R2 with respect to the wiring bonding portion 62. The angle R2 formed by the vertical portion 64b and the wiring bonding portion 62 is approximately 90 degrees. This angle R2 may effectively be 90 degrees.

The following will describe a case where a wire 71b is bonded to the front surface of the parallel portion 65 of the lead frame 160 described above. The semiconductor unit 30 is encapsulated with the encapsulating member 29. As described earlier, the components included in the semiconductor unit 30 include components that have poor adhesion to the encapsulating member 29. As one example, the encapsulating member 29 has poor adhesion to the solder that is the bonding member 46. For this reason, there is a risk that the encapsulating member 29 that encapsulates the semiconductor unit 30 may peel off at a part where the encapsulating member 29 is in close contact with the bonding member 46. Peeling of the encapsulating member 29 will spread out. When the peeling spreads to the wire bonding portion 71b1 of the wire 71b, the wire 71b may break due to the peeling. In the configuration of the comparative example, the lead frame 160 is rectangular in shape when viewed from the side. This means that even when the peeling of the encapsulating member 29 spreads for example along the arrows A1 and A2 drawn with broken lines in FIG. 8, since the one end of the wire 71b is located away from the point where peeling occurs, there is increased probability that the wire 71b will not be affected by the peeling. Peeling of the encapsulating member 29 that spreads along the arrows A1 and A2 drawn with broken lines is suppressed at the connections between the parallel portion 65 and the vertical portions 64a and 64b. This means that the peeling of the encapsulating member 29 does not reach the wire 71b. This is expected to prevent the wire 71b from breaking. Note that in reliability tests (power cycle tests) of this semiconductor unit 30, peeling tends to occur more in the periphery of the chip bonding portion 61 of the lead frame 160 encapsulated by the encapsulating member 29 than in the periphery of the wiring bonding portion 62. Accordingly, peeling of the encapsulating member 29 is more susceptible to spreading in the direction of the arrow A2 than in the direction of the arrow A1. This is due to localized heat generation by the semiconductor chip 50c during the power cycle test. The localized heat generation by the semiconductor chip 50c heats the chip bonding portion 61 and the vertical portion 64a, so that peeling along the chip bonding portion 61 and the vertical portion 64a (see the arrow A2) tends to spread.

However, in reality, when the wire 71b is bonded using ultrasonic waves while the wire 71b is being pressed onto the front surface of the parallel portion 65, as depicted in FIG. 9, the parallel portion 65 will be deformed toward the insulated circuit board 40 (in the −Z direction) by the pressing force applied during the bonding of the wire 71b. Accordingly, the wire 71b is not reliably bonded to the parallel portion 65 of the lead frame 160. The lead frame 160 will become damaged. As a result, there is concern over a fall in reliability of semiconductor devices including this type of lead frame 160.

To reliably bond the wire 71b to the parallel portion 65 of the lead frame 160, both angles R1 and R2 could be conceivably inclined in the same way at acute angles to make the lead frame 160 trapezoidal when viewed from the side. In this case, although the deformation of the parallel portion 65 is prevented compared to when the angles R1 and R2 are 90 degrees, it is not possible to completely suppress such deformation.

For this reason, the lead frame 60 according to the present embodiment includes the chip bonding portion 61, the wiring bonding portion 62, and the wiring portion 63. The chip bonding portion 61 is bonded via a bonding member to the output electrode 52c on the front surface of the semiconductor chip 50c. The wiring bonding portion 62 is bonded to the front surface of the wiring board 43d. The wiring portion 63 joins the chip bonding portion 61 and the wiring bonding portion 62 across the gap G between the wiring boards 43d and 43b.

The wiring portion 63 further includes the vertical portion 64, the parallel portion 65, and the inclined portion 66. The lower end of the vertical portion 64 is connected to the chip bonding portion 61, and the upper end of the vertical portion 64 rises vertically from the chip bonding portion 61. That is, the angle R of the vertical portion 64 with respect to the chip bonding portion 61 is a right angle (90 degrees). The parallel portion 65 is connected to the upper end of the vertical portion 64, and extends from this upper end in parallel to the wiring boards 43b and 43d and the semiconductor chip 50c. The inclined portion 66 is inclined from the parallel portion 65 toward the wiring bonding portion 62. Even when the wire 71b is bonded to the front surface of the parallel portion 65 of the wiring portion 63 included in the lead frame 60, deformation of the parallel portion 65 toward the insulated circuit board 40 side is suppressed. In particular, it has been confirmed that deformation of the parallel portion 65 toward the insulated circuit board 40 is more thoroughly suppressed when the angle α is between 30 degrees and 60 degrees compared to the case in FIG. 8 and a case where the angles R1 and R2 in FIG. 8 are the same angles and are acute. In addition, it has been confirmed that when the angle α is 30 degrees or more and less than 45 degrees, deformation of the parallel portion 65 toward the insulated circuit board 40 side is suppressed even more thoroughly.

Note that the angle R of the vertical portion 64 is not limited to 90 degrees, and as described earlier, it has been confirmed that deformation of the parallel portion 65 toward the insulated circuit board 40 is suppressed even when the angle R is 80 degrees or more and less than 90 degrees. In particular, when the angle R is 80 degrees or 85 degrees, it is preferable for the angle α to be 30 degrees or more and 60 degrees or less, and more preferably 30 degrees or more and 45 degrees or less.

It is preferable for the wire 71b to be bonded to the vertical portion 64 side of the parallel portion 65. When the wire 71b is bonded to the vertical portion 64 side of the parallel portion 65, the pressure applied during bonding is supported by the vertical portion 64, which more thoroughly prevents deformation of the parallel portion 65. Accordingly, it is possible to reliably bond the wire 71b to the parallel portion 65 of the lead frame 60. In the semiconductor unit 30 that is encapsulated by the encapsulating member 29 and includes the lead frame 60, as described earlier, even when peeling of the encapsulating member 29 occurs near the wiring bonding portion 62 and such peeling spreads from the wiring bonding portion 62 to the inclined portion 66, the peeling will not reach the wire 71b since it is positioned away from the location of the peeling. This means that breakage of the wire 71b due to the peeling is also prevented. As a result, a fall in the reliability of the semiconductor device 10 including the lead frame 60 is also suppressed.

Note that since the vertical portion 64 extends vertically upward from the chip bonding portion 61, the height H from the front surface of the semiconductor chip 50c to the parallel portion 65 is ensured. By increasing the height H, the influence of localized heat generation by the semiconductor chip 50c on the parallel portion 65 connected to the vertical portion 64 is reduced. Accordingly, even when the encapsulating member 29 peels off near the chip bonding portion 61 of the lead frame 60, such peeling is not susceptible to spreading from the chip bonding portion 61 to the vertical portion 64.

Also, as mentioned earlier, a sufficient height H from the front surface of the semiconductor chip 50c to the parallel portion 65 is ensured. When manufacturing the semiconductor device 10, before encapsulating with the encapsulating member 29, a coating material that has a thermoplastic resin as a main component is sprayed into the housing regions 21el to 21e3 of the case 20. That is, the surface of the semiconductor unit 30 becomes covered with a film. This film protects the semiconductor units 30. In particular, adhesion of the semiconductor units 30 via this film to the encapsulating member 29 is improved. The coating material is sprayed onto the target by air spraying from a nozzle of a coating device. As one example, when the height from the nozzle to the target is around 5 mm, the application of the material by the nozzle will spread to a diameter of around 8 mm on the target. The film is applied across the entire surface of the semiconductor unit 30. As described earlier, adhesion of the encapsulating member 29 to the solder that is the bonding member 46 is poor. For this reason, it is preferable for the film to be appropriately applied in the periphery of the chip bonding portion 61 and the wiring bonding portion 62 of the lead frame 60. For this reason, for the wiring portion 63 of the lead frame 60, a vertical portion 64 is provided at the chip bonding portion 61 to ensure a sufficient height H from the front surface of the semiconductor chip 50c to the parallel portion 65.

Since a sufficient height H is ensured, it is possible for the nozzle to reliably apply the film even in the periphery of the heel portion 61b (in the −X direction) of the chip bonding portion 61 of the lead frame 60. Accordingly, in each semiconductor unit 30, the film is applied to the front surface of the insulated circuit board 40, the semiconductor chips 50a to 50d, the wires 70a, 70b, 71a, 71b, 71c, 71d, 72a, and 72b, and the surface of the lead frame 60.

The lead frame 60 connects the wiring board 43d and the output electrode 52c of the semiconductor chip 50c. This means that the chip bonding portion 61 of the lead frame 60 is located higher than the wiring bonding portion 62. In some configurations, the lead frame 60 may also connect wiring boards together. Also, in place of the semiconductor chip 50c, the lead frame 60 may be connected to other elements. That is, the lead frame 60 may connect any different conductive portions across a gap.

### Modification 1

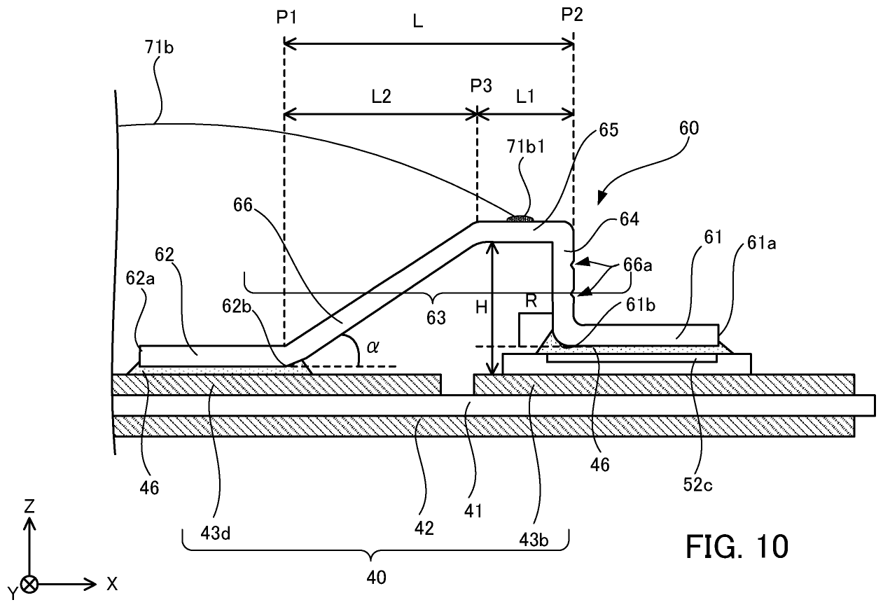

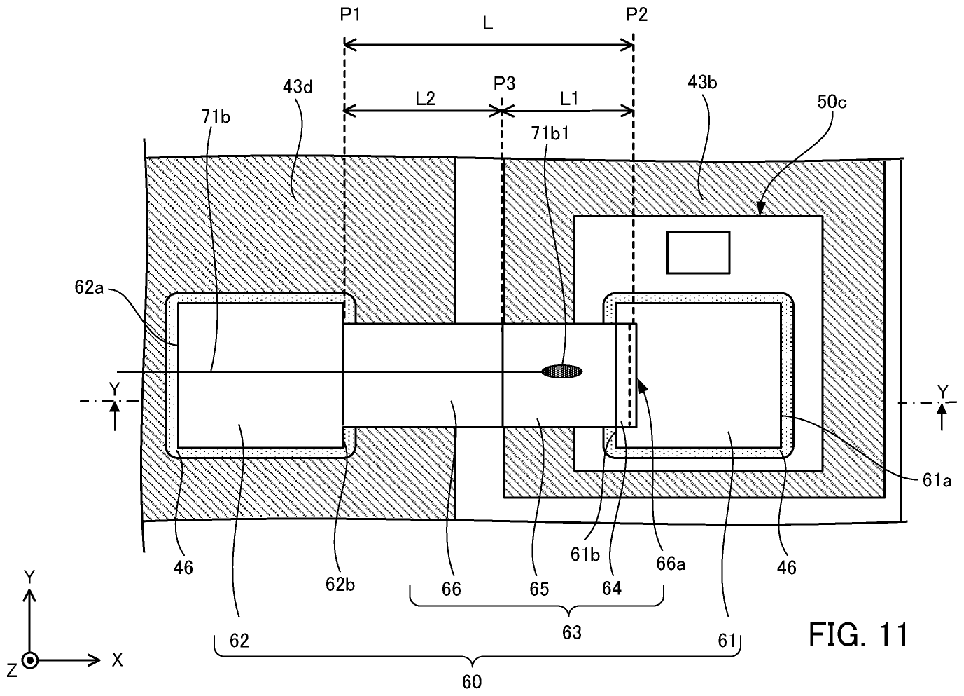

A semiconductor unit 30 according to Modification 1 is also as depicted in FIG. 3. However, the semiconductor unit 30 according to Modification 1 has a different lead frame 60. The lead frame 60 in Modification 1 will be described using FIGS. 10 and 11. FIG. 10 is a cross-sectional view of a lead frame included in a semiconductor device according to the present embodiment (Modification 1), and FIG. 11 is a plan view of the lead frame included in the semiconductor device according to the present embodiment (Modification 1). Note that FIGS. 10 and 11 correspond to FIGS. 6 and 7. FIG. 10 is a cross-sectional view taken along the chain line Y-Y in FIG. 11.

In the lead frame 60 according to Modification 1, one or more grooves 66a are formed in a front surface (that is, the surface facing the +X direction) of the vertical portion 64. Modification 1 is an example configuration where two grooves 66a are formed. The grooves 66a are formed as to be perpendicular to the long axis of the wire bonding portion 71b1 of the wire 71b. The grooves 66a are continuously formed in a straight line so as to cross the width (the +Y direction) of the vertical portion 64. The depth and width (that is, the length in the wiring direction of the lead frame 60) of the grooves 66a are set within a range that does not affect the conduction of electricity by the vertical portion 64. As one example, the depth may be 20% or more and 45% or less of the thickness of the vertical portion 64. Further, the grooves 66a do not need to be continuous. That is, the grooves 66a may be formed in the shape of linear broken (that is, discontinuous) lines. The grooves 66a do not need to be linear, and as examples, may be V-shaped, wavy, or jagged.

The semiconductor unit 30 including this lead frame 60 is encapsulated by the encapsulating member 29. When doing so, there is a risk of the encapsulating member 29 peeling off in a range where the encapsulating member 29 comes into contact with the solder of the bonding member 46 that bonds the chip bonding portion 61 and the output electrode 52c of the semiconductor chip 50c. When this peeling spreads from the chip bonding portion 61 along the vertical portion 64, the grooves 66a formed in the vertical portion 64 suppress the peeling from spreading further. This prevents the peeling from reaching the wire 71b, which prevents breakage of the wire 71b due to the peeling. As a result, deterioration in the reliability of the semiconductor device 10 including the lead frame 60 is also suppressed.

Note that one or more grooves 66a may also be formed in the front surface (the surface that faces the −X direction) of the inclined portion 66. The groove (s) 66a formed in the inclined portion 66 is/are the same as the grooves 66a formed in the vertical portion 64. That is, the groove (s) 66a is/are formed so as to be perpendicular to the long axis of the wire bonding portion 71b1 of the wire 71b. The grooves 66a may be continuously formed in straight lines so as to cross the width (the ±Y direction) of the inclined portion 66. The depth and width (that is, the length in the wiring direction of the lead frame 60) of the grooves 66a may be the same as above, and the grooves 66a may be discontinuous. There is a risk that the encapsulating member 29 will peel off in the range where the encapsulating member 29 comes into contact with the solder of the bonding member 46 that bonds the wiring bonding portion 62 and the wiring board 43d. When such peeling spreads from the wiring bonding portion 62 along the inclined portion 66, the grooves 66a formed in the inclined portion 66 suppress the peeling from spreading further.

### Modification 2

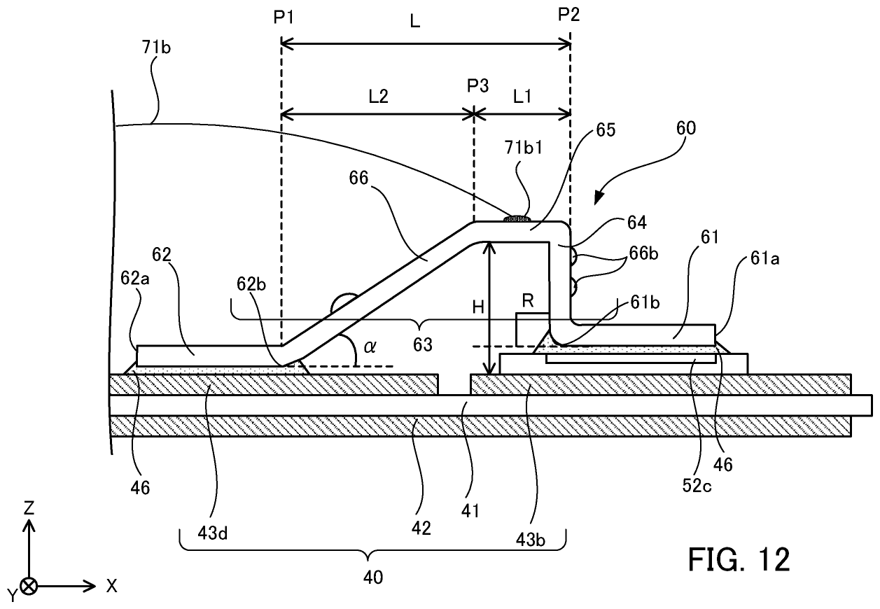

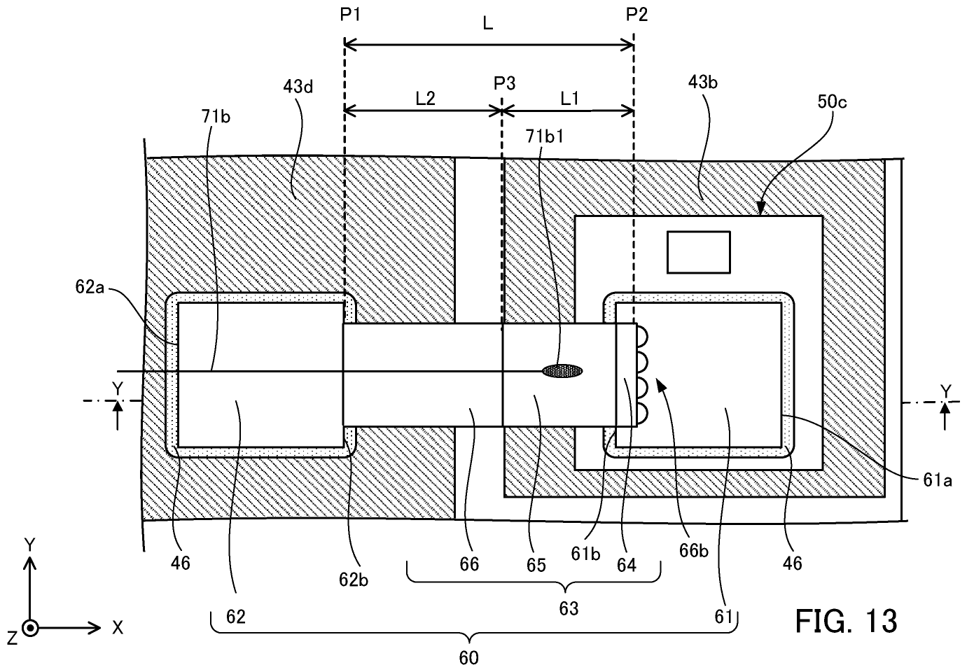

In a second modification, a configuration where protrusions are formed on the lead frame 60 in FIGS. 6 and 7 will be described with reference to FIGS. 12 and 13. FIG. 12 is a cross-sectional view of a lead frame included in a semiconductor device according to the present embodiment (Modification 2), and FIG. 13 is frame included in the a plan view of the lead semiconductor device according to the present embodiment (Modification 2). Note that FIGS. 12 and 13 correspond to FIGS. 6 and 7. FIG. 12 is a cross-sectional view taken along a chain line Y-Y in FIG. 13. A semiconductor unit 30 according to Modification 2 is also as depicted in FIG. 3.

In the lead frame 60 according to Modification 2, a plurality of protrusions 66b are formed on a front surface (that is, the surface facing the +X direction) of the vertical portion 64 of the wiring portion 63. Modification 2 is a configuration where the protrusions 66b are hemispherical and two rows of four protrusions 66b are formed. In this case, the protrusions 66b are formed so as to be perpendicular to the wire bonding portion 71b1 of the wire 71b. The four protrusions 66b are merely one example, and so long as the width (±Y direction) of the vertical portion 64 is roughly covered, one, two, three, or five or more protrusions 66b may be used in keeping with the area of each protrusion 66b. Two rows are merely one example arrangement, and there may be one row, or three or more rows. The protrusions 66b are not limited to being hemispherical and may be formed in any convex shape, such as triangular pyramid, quadrangular pyramid, or cube. The protrusions 66b may be linear and continuous so as to cross the width (the ±Y direction) of the inclined portion 66, and may be formed so as to be convex in cross section. Further, the height and width (that is, the length of the lead frame 60 in the wiring direction) of the protrusions 66b in this configuration may be within a range that does not interfere with the wire 71b that has been laid out.

As described in Modification 1, the semiconductor unit 30 including the lead frame 60 is encapsulated by the encapsulating member 29. When doing so, there is a risk of the encapsulating member 29 peeling off in a range where the encapsulating member 29 comes into contact with the solder of the bonding member 46 that bonds the chip bonding portion 61 and the output electrode 52c of the semiconductor chip 50c. When this peeling spreads from the chip bonding portion 61 along the vertical portion 64, further spreading of peeling is suppressed by the protrusions 66b formed on the vertical portion 64 of the lead frame 60. This means that breakage of the wire 71b due to the peeling is also prevented. As a result, deterioration in reliability of the semiconductor device 10 including the lead frame 60 is also suppressed.

Note that a plurality of these protrusions 66b may also be formed on the front surface (that is, the surface that faces the −X direction) of the inclined portion 66. This plurality of protrusions 66b formed on the inclined portion 66 are the same as those formed on the vertical portion 64. That is, the plurality of protrusions 66b are formed so as to be perpendicular to the long axis of the wire bonding portion 71b1 of the wire 71b. So long as the width (the ±Y direction) of the inclined portion 66 is roughly covered, the plurality of protrusions 66b formed on the inclined portion 66 may also be one or more protrusions and arranged in one or more rows in keeping with the area of each protrusion 66b. There is a risk of the encapsulating member 29 peeling off in a range where the encapsulating member 29 comes into contact with the solder of the bonding member 46 that bonds the wiring bonding portion 62 and the wiring board 43d. When such peeling spreads from the wiring bonding portion 62 along the inclined portion 66, the plurality of protrusions 66b formed on the inclined portion 66 suppress the peeling from spreading further.

According to the present disclosure, breakage of wires is suppressed, which prevents a drop in reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first conductive portion and a second conductive portion provided with a gap in between;
connection wiring, including:
a first bonding portion bonded to a front surface of the first conductive portion,
a second bonding portion bonded to a front surface of the second conductive portion, and
a wiring portion that straddles the gap and connects the first bonding portion and the second bonding portion; and
a wire bonded to the wiring portion, wherein the wiring portion includes:
a vertical portion that extends, from a lower end thereof to an upper end thereof, perpendicularly to the front surface of the first conductive portion, the lower end thereof being connected to the first bonding portion;
a parallel portion that extends in parallel to the first conductive portion and the second conductive portion from the upper end of the vertical portion, the parallel portion having, on a front surface thereof, a wire bonding portion to which one end of the wire is bonded; and
an inclined portion that extends inclinedly from the parallel portion toward the second bonding portion.

2. The semiconductor device according to claim 1,
wherein the first conductive portion is a main electrode provided on a front surface of a semiconductor chip.

3. The semiconductor device according to claim 1,
wherein an angle of inclination between the inclined portion and the second bonding portion is 30 degrees or more and 60 degrees or less.

4. The semiconductor device according to claim 1,
wherein the wiring portion has at least one groove protrusion, or at least one which is arranged perpendicular to a wiring direction of the wiring portion, formed on a front surface thereof between the wire bonding portion and the second bonding portion.

5. The semiconductor device according to claim 1, wherein in a plan view of the semiconductor device,
the parallel portion of the wiring portion has a first side and a second side, the second side being closer to the vertical portion than the first side; and
the wire bonding portion is bonded to the second side of the parallel portion.

6. The semiconductor device according to claim 1, further comprising:
a coating applied to the first conductive portion, the second conductive portion, and the wire; and
an encapsulating member that adheres to the coating.
